(19) United States
(12) Patent Application Publication
(10) Pub. No.: US 2012/0039117 A1
(43) Pub. Date: Feb. 16, 2012

(54) DESTRUCTION OF DATA STORED IN PHASE CHANGE MEMORY

(75) Inventor: Gary Edward Webb, Cumming, GA (US)

(73) Assignee: Gary EDWARD WEBB, Cumming, GA (US)

(21) Appl. No.: 13/210,210

(22) Filed: Aug. 15, 2011

Related U.S. Application Data
(60) Provisional application No. 61/374,080, filed on Aug. 16, 2010.

(51) Int. Cl. G11C 11/00

(52) U.S. Cl. 365/163; 365/148

(57) ABSTRACT

A mechanism and means by which the data information pattern stored in Phase Change Memory PCM (21) can be quickly destroyed and made unreadable upon the receipt of a destruction stimuli(11) by the application of a targeted thermal heat source generated by an internal integrated thermal heater (26), a heat source mounted under the PCM (28), on top of the PCM (29), within the PCB (30), or an externally generated heat source (27). Such an operation is non-destructive and while the stored data is rendered unreadable, the physical PCM device is unharmed and can be used again.

### CROSS-REFERENCE TO RELATED APPLICATIONS

This application claims the benefit of PPA Ser. No. 61/374,080 filed 2010 Aug 16 by the present inventor.

### FEDERALLY SPONSERED RESEARCH

None.

### SEQUENCE LISTING

None.

### BACKGROUND

1. Field of invention

This invention relates to memories, particularly relating to Phase Change Memory (PCM), and generally to methods, methods of fabrication, and apparatus for destroying data patterns stored in such memory

This invention applies to both PCM memories and systems using such memories and any memory device or system that exhibits the thermal characteristics of PCM memories where the stored state is lost as a result of a thermal event.

2. Background of invention

Phase Change Memory (PCM) is a type of non-volatile memory typically used in computers and other electronic devices. It is use is starting to become more widespread as a replacement for other Flash memory technologies.

PCM memory is based on the properties of certain materials to switch between the complete or general amorphorous and complete or general crystalline state. The states are distinguishable because the more disordered amorphorous state generally exhibits a higher resistance than does the more ordered lattice structure of the crystalline state. These states can be used to store bits of data. The invention first presented by Ovshinsky in patent U.S. Pat. No. 3,271,591 describes such a memory element.

The states found on phase change memory can be induced reversibly from the amorphorous state to the crystalline state and from the crystalline state to the amorphorous state in response to temperature changes. The temperature changes can be achieved by several methods including temperature induced as a result of a laser being directed through the phase change memory, a current driven through the memory, or a current fed through a resistive heater element found in close proximity to the phase change memory or material,

PCM memory is based on the properties of chalcogenide glass containing one or more chalcogenide elements such as sulfur, selenium, and tellurium. These devices commonly make use of a chalcogenide alloy of germanium, antimony, and tellurium (GeSbTw) called GST., though many new alloys and improvements are being introduced with improvements in switching speeds while lowering of the energy required to switch between states.

Inventions such as those later presented by Ovshinsky in patents U.S. Pat. Nos. 5,341,328 and 5,687,112 show the improvements made in increased switching speeds while lowering the energy required to switch between the amorphorous and crystalline states. This latter being reduced to less than 0.1 to 2 nanojoules for a few nanoseconds by the mid-1990s.

The invention described by Hamann, et al in U.S. Pat. No. 7,129,560 and US2,418,8668A1 describes a thermal memory cell, some methods to create it, and provides data on the temperature and current required to affect the state. An assembly for generating targeted near-field thermal heat is presented in patent application US22101673A1. Lee, US28090324A1, provides a method of forming a sublithographic heater on phase change memories.

PCM memory writes, or state changes, are accomplished by the controlled application of heat to a specific PCM cell or plurality of cells. This is typically done by applying a voltage to a row and column element which causes current to flow through the resistive element which causes heat. The heat will cause the material at the targeted location to change state. There are many methods of applying the heat and localizing it to a particular location. Controlling the heat such that is remains localized and of a finite intensity and duration is one of the PCM challenges that are being addressed by the industry. Without careful and specific methods, the heat generated during the write process is capable of causing the PCMs data state to be lost and not recoverable.

If the PCM device is subjected to a high temperature, it will become amorphorous and the stored information content represented in the PCM device will be lost. This is currently an industry challenge faced during the manufacturing process of equipment containing PCM memory component devices. The manufacturing process of soldering components such as the PCM devices to the printed circuit board (PCB) involves raising the PCB and the unsoldered components to an elevated temperature high enough to melt and flow the metal used in the soldering process. In current no-lead process typically will raise the entire board and components to temperatures of over 260C degrees. This high temperature is sufficient to quickly erase and stored state contained in the PCM memory devices. Hence an industry challenge of using preprogrammed PCM memory devices.

There is a class of computers and other electronic equipment that store sensitive data that should not be allowed to be disclosed or retrieved by others other than the intended person, system, or use.

The data stored and transmitted on such devices are typically encrypted by cryptography means and mechanisms. Additionally, Tamper Responsive devices are frequently designed to destroy any data contained within it if the device is stolen, lost, breached, or otherwise compromised . Additionally such action is also frequently initiated upon the detection of an action that is perceived to be an attempt to read the data or breach the security of the device.

Such devices, mechanisms, and policies are requirements for equipment holding sensitive data such as credit card information , sensitive encryption keys, classified governmental intelligence or sensitive commercial data, or classified data as typically used by the military in battlefield devices and systems. Such devices need the ability to quickly and completely destroy their sensitive informational content at a moments notice.

Equipment and systems designed for use in military, governmental, or industrial applications have such a requirement as does equipment, devices, and systems designed for compliance with PCI compliance where customer information such as credit card information is stored “at rest”. Any equipment or device that contains sensitive information must be Tamper Responsive self-destruct or completely destroy that information along with any encryption keys upon the detection of an attempt, real or perceived, to read the sensitive data, keys, or gain knowledge of the mechanisms in place to detect and prevent such an action.

Events that might trigger such a self-destruction action include, bit are not limited, to detection of a physical case opening, extreme vibration, drilling, x-ray, rapid temperature drop, removal of power, relocation of device, physical movement, an internal timer or watchdog trigger, or the absence or delay of an external physical or informational polling event, among others.

Kumhyr et al presents one method of enabling a destruction trigger of data in U.S. Pat. No. 7,717,326

### SUMMARY OF INVENTION

A self-destruct Tamper Responsive mechanism that destroys the stored state of a PCM memory element by applying intentional heat to the PCM element for a very short period, effectively making the device completely unreadable in an extremely short and finite period of time.

Such an application of heat results in the PCM material becoming amorphorous in an uncontrollable manner thus losing any stored patterns. Because only the data pattern contents are destroyed, not necessarily the physical memory device, the equipment remains intact and can later be redeployed or repurposed upon reloading of data patterns within the PCM material.

The heat source can be built into the PCM device or applied externally. The heat source can be the same mechanism typically used by the PCM structure to write or erase individual cells or a plurality of cells in normal operation or it can be an additional element added within the PCM device substrate. If applied externally, the heat source can be a heat source attached to the PCM package, or positioned under or over such a PCM component package, or positioned within PCB or other location within or close to the device enclosure. The invention extends to PCM memory elements packaged in custom integrated circuits and System on Chip (SOC) implementations.

In the case of the external sources, they can be retrofitted into existing equipment utilizing PCM memory elements. Similarly, new equipment can be produced with existing PCM components. If the invention is implemented inside the component, then neither the board or box manufacturing process is substantially modified.

The heat source can be generated by the presence of electrical current, heat, light, explosion, chemical reaction, radiation, magnetic pulse, or other means of generating the required elevated thermal state.

The activation can be initiated by any means typically used to trigger such actions in other traditional self-destruction mechanisms including physical detection, vibration, freezing, x-rays, pressure, removal of power, or other triggering signal.

The destruction can be initiated via a physical impulse on a signal wire, a command sequence on a signal wire or other data path, a voltage , a pressure fluctuation, or the absence of any of these or other stimuli. Such a triggering stimuli mechanism can be implemented on the board or within the PCM component itself.

### OTHER ART

One method used in the industry to quickly wipe the contents of a memory array is to use battery-backed up volatile static memory and then to remove the battery from the volatile array upon the detection of an attempted attack or other trigger with a small sensor or microprocessor.

Because a battery is required, this approach has several detriments: increased physical weight and size, poor shock resistance, increased production cost, restriction of the environmental range of the memory to the range of the battery, reduced operational service life of the memory to the service life of the battery.

In addition to these detriments, a battery backed up sram does not offer a method of providing the function at the semiconductor component level.

Another method of destroying data uses an electromagnetic pulse (EMP) created by the employment of a xenon flash tube such as the apparatus claimed in Kumhyr, et al US28112300A1.

### DESCRIPTION OF INVENTION

FIG. 1 presents the means by which a stimulus will initiate the destruction of stored data patterns and information contained in the phase change memory. The initial destruct stimuli 11 can be initiated as physical destruct voltage or signal, a communication request, a tamper detection device, a proximity or geographic sensor signal, a fire or vibration signal, a watchman dead-man circuit that sends the destruct stimuli as a result of the absence or delay of other expected stimuli. A destruct message or signal 12 is then presented to the destruct mechanism 13. The destruct mechanism applies the destruct request and sends the destruct signal 14 to a thermal heat source 15. This thermal heat source can be embodied as an electrical heater, a laser, a chemical heat source, a light source, an electronic magnetic pulse, or an explosive device, among others. The heat generated 16 will be applied to the phase control memory material 17 which will cause an uncontrollable change of its state, erasing all data patterns contained within its structure.

FIG. 2 shows a typical phase change memory (PCM) device 21 comprised of a phase change memory material 22, electronic control circuitry 23, and an attachment mechanism 24. The phase change memory (PCM) is usually attached to a printed circuit board (PCB) 25, though it could be integrated into a system on chip (SoC) or other package reduction technique.

FIG. 3 shows the inclusion of a thermal heat substrate 26 within the phase change memory (PCM) device 21. This thermal producing element, when activated, will cause the state of the PCM to be changed, quickly erasing any data pattern contained within its structure.

The thermal heating element can implemented as a separate substrate or can be incorporated into the existing electronic control circuitry 23.

FIG. 4 shows a typical phase change memory (PCM) device 21 comprised of a phase change memory material 22, electronic control circuitry 23, and an attachment mechanism 24 where an external thermal heat source 27 is provided that when activated, will cause the state of the PCM to be uncontrollably changed, quickly erasing any data pattern contained within its structure. This external heat source could be produced by electrical, chemical, or other means.

FIG. 5 shows an embodiment of the invention where the external heat source is implemented as a thermal heater 28 mounted under an unmodified phase change memory device 21.

FIG. 6 shows an embodiment of the invention where the external heat source is implemented as a thermal heater 29 mounted on top of an unmodified phase change memory device 21.

FIG. 7 shows an embodiment of the invention where the external heat source is implemented as an embedded thermal heater 30 incorporated into the printed circuit board 25.

### PREFERRED EMBODIMENT

FIG. 3 shows the preferred embodiment where the thermal heating element is integrated into the Phase Change Memory (PCM) device.

### DRAWINGS

FIG. 1 is a overview of how the intent to destruct results in the erasure of data

FIG. 2 presents a typical phase change memory (PCM) device structure

FIG. 3 presents the inclusion of a thermal heater element inside the PCM

FIG. 4 presents the inclusion of a thermal heater element external to the PCM

FIG. 5 presents the inclusion of an external thermal element under the PCM

FIG. 6 presents the inclusion of an external thermal element attached to the PCM

FIG. 7 presents the inclusion of an external thermal element embedded in the PCB Printed Circuit Board

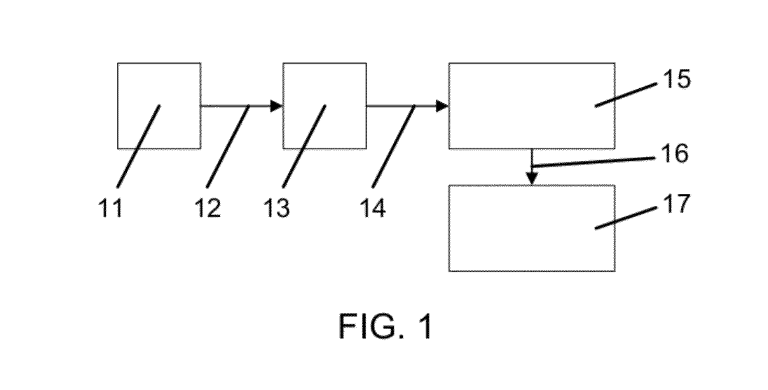

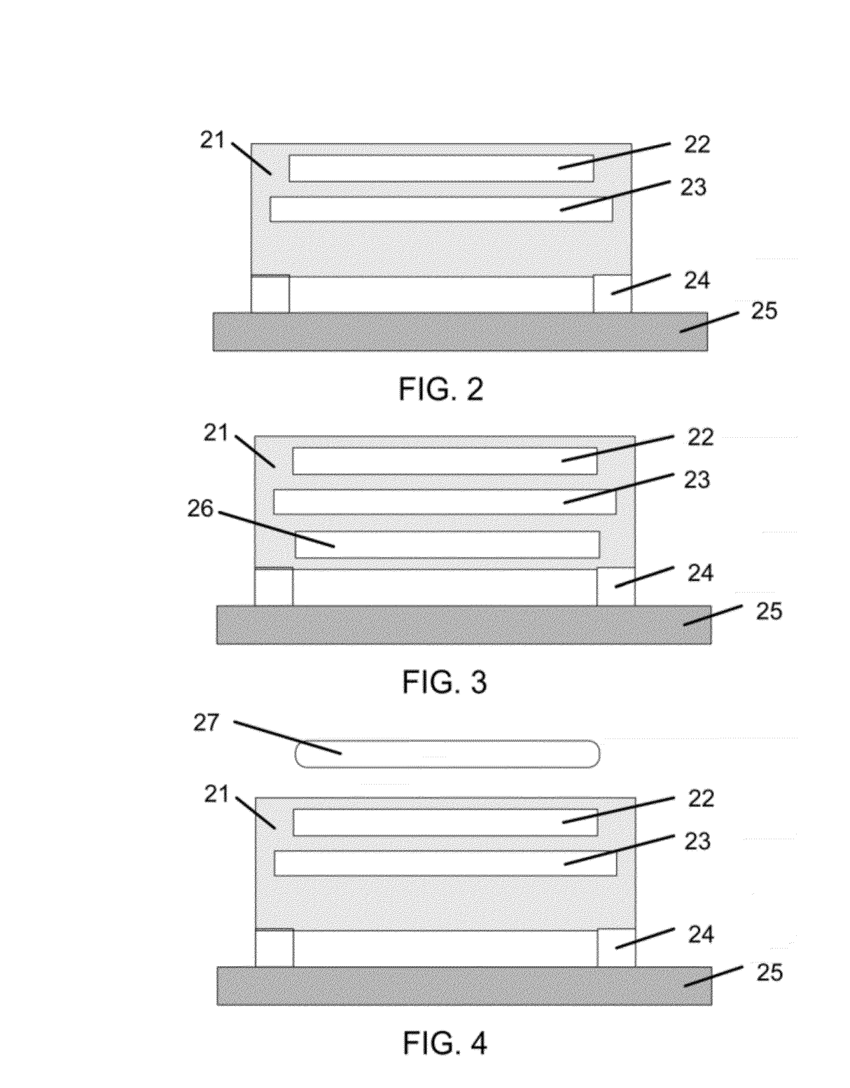

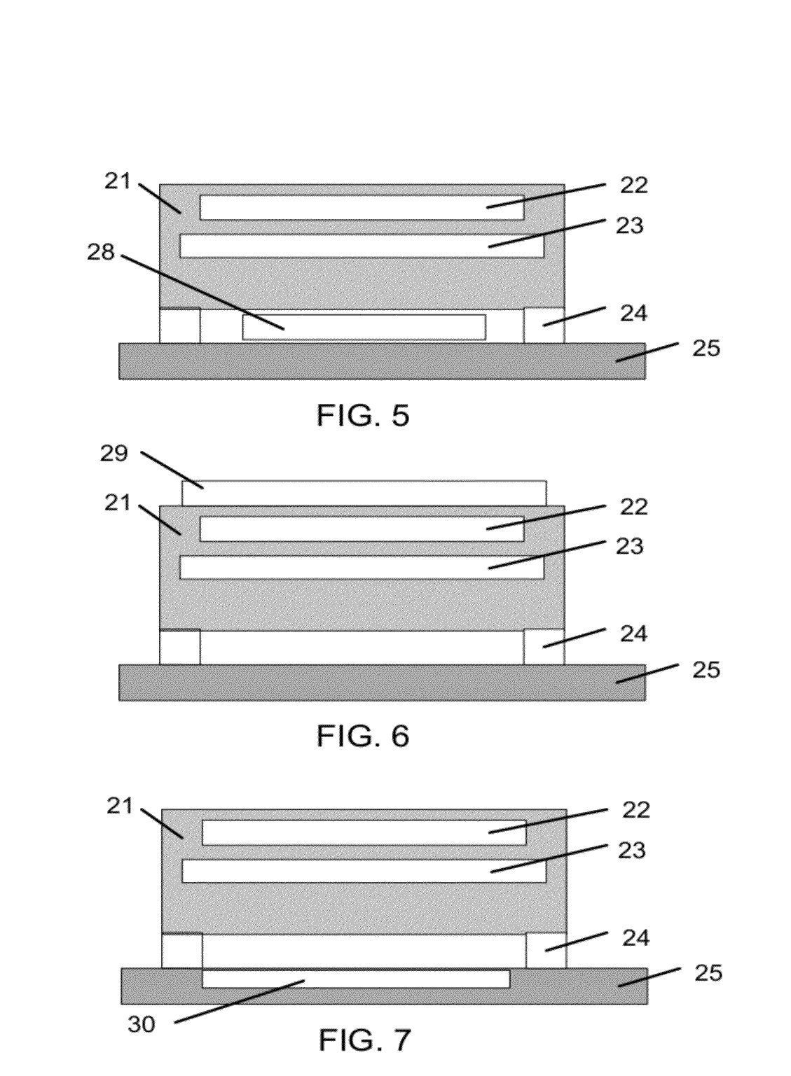

### REFERENCE NUMERALS

11 destruct stimuli
12 destruct message
13 destruct mechanism
14 destruct signal
15 thermal heat source
16 thermal heat
17 phase change memory material
21 phase change memory device (PCM)
22 phase change material
23 electronic control circuitry
24 attachment mechanism
25 printed circuit board (PCB) or other substrate
26 thermal heater substrate
27 thermal heat source
28 thermal heater
29 thermal heater
30 embedded thermal heater

1. A memory, comprising:
a. memory element whose stored state or data pattern may be destroyed with the application of appropriate heat without damaging the memory element
b. electronic control circuit

2. Thermal heating unit that when activated in close enough proximity, will erase the stored state of the memory of claim 1, destroying any data pattern held within

3. A means of activating the thermal heating unit of claim 2 when the data pattern content of the memory of claim 1 is desired to be destroyed.
